(19) United States
(12) Patent Application Publication
(10) Pub. No.: US 2018/0014402 A1
(43) Pub. Date: Jan. 11, 2018

(54) WIRING BOARD AND METHOD FOR DESIGNING SAME

(71) Applicant: NEC Corporation, Minato-ku, Tokyo (JP)

(72) Inventor: Kazuhiro KASHIWAKURA, Tokyo (JP)

(73) Assignee: NEC Corporation, Minato-ku, Tokyo (JP)

(21) Appl. No.: 15/534,626

(22) PCT Filed: Jan. 15, 2016
(86) PCT No.: PCT/JP2016/000205

§ 371 Date: Sep. 7, 2017

(30) Foreign Application Priority Data
Jan. 21, 2015 (JP) 2015-009817

(51) Int. Cl. H05K 1/02; H05K 1/03; H05K 3/06

(52) U.S. Cl. CPC H05K 1/0298; H05K 3/064; H05K 1/0366; H05K 1/0237; H05K 1/0245; H05K 1/0248

(57) ABSTRACT

[Problem] To achieve a wiring board capable of suppressing the difference in the amount of delay between two signal wirings constituting differential signal wirings, while securing flexibility in design.

[Solution] A wiring board is configured to include a first insulating layer 1, a first signal wiring 2 and a second signal wiring 3. The first insulating layer 1 includes fibers 4 having the long axis in a first direction and aligned approximately parallel to each other at a first interval and an insulating material 5 filling gaps between the fibers 4 of the first direction. The first signal wiring 2 is formed approximately parallel to the first direction on the first insulating layer 1. The second signal wiring 3 is formed parallel to the first signal wiring 2 such that the interval between the first and second signal wirings 2 and 3 be approximately an integral multiple of the first interval, and the second signal wiring 3 transmits a differential signal of a signal transmitted on the first signal wiring 2.

### TECHNICAL FIELD

The present invention relates to a wiring board for transmitting high frequency signals and, in particular, to a wiring board for transmitting differential signals of a high frequency range.

### BACKGROUND ART

With the development of an information and communication society, data communication and signal processing have come to be performed in a large capacity and at high speed, and increase in speed of transmitted signals is progressing. With the progress of increasing the signal speed, the influence of loss and delay of signals in their transmission on a wiring board has become not negligible. Accordingly, signal wirings of an electronic device such as for processing a large capacity of data at high speed need to be designed with wiring widths and wiring lengths satisfying required characteristics. On the other hand, in a wiring board for mounting semiconductor devices and the like which are compatible with the increase in capacity and speed, the number of signal wirings increases and also the wiring density does, and accordingly, the wiring design has become complicated. Therefore, in a wiring board for transmitting signals at high speed, it is desirable that flexibility in determining line widths, arrangement positions and the like of the signal wirings is secured as much as possible.

The signal transmission speed has become beyond 10 Gbps (Giga bit per second), and increasing of the speed has progressed further into giga ranges such as 28 Gbps and 56 Gbps, and accordingly, differential signal wiring has become a mainstream in signal wiring on a wiring board such as a printed circuit board. There, differential signals are transmitted in the form of two signals having opposite phases on two signal wirings. To correctly process the differential signals at an output side, it is required that the difference in delay time between the two signals having opposite phases is suppressed to be as small as possible. However, if a difference is generated between delay times of the two signals having opposite phases by the influence of electrical characteristics of signal wirings and insulating layers, a state at the output side deviates from the opposite phase state, and it accordingly may become impossible for a semiconductor device at the output side to correctly perform signal detection. Therefore, in a wiring board such as a printed circuit board for transmitting high speed differential signals, it is required that the delay difference between the two signals is suppressed.

To suppress loss and delay of a signal on a wiring board, it has been conducted to decrease the dielectric permittivity of an insulating material constituting the wiring board. Further, in a wiring board such as a printed circuit board, a glass cloth may be used as a structural material for the purpose of maintaining the mechanical strength of the board. Glass fibers in such a glass cloth have a higher relative dielectric constant than an insulating layer having a reduced dielectric permittivity.

A glass cloth used for a printed circuit board is formed by plain weaving of glass fibers bundled into some number of fiber bundles, in the longitudinal and lateral directions. In the glass cloth, gaps are generated between the fiber bundles aligned in the longitudinal and lateral directions. Accordingly, a signal transmitted on a signal wiring formed on the printed circuit board passes portions where the glass cloth is present and also portions where only an insulating resin is present. Because the relative dielectric constant is different between the glass fibers and the insulating resin in the glass cloth, there occurs a difference in the amounts of delay and loss of a signal between when passing a portion having the glass fibers and when passing a portion having only the resin. As a result, there occurs a difference in the amount of delay between signals transmitted on two differential signal wirings each passing different positions from those the other passes. When the difference in the amount of delay between two signals constituting differential signals becomes large, phase deviation between the signals becomes large, and there accordingly occurs abnormality in signal processing at the output side as a result of an increase in the insertion loss. Therefore, it is desirable that there is a technology which, in differential signal wirings formed on a printed circuit board, can suppress the difference in the amount of delay between the signals while securing flexibility in design. As a technology for suppressing signal delay in a wiring board for transmitting high speed differential signals, for example, a technology of Patent Literature 1 (PTL 1) is disclosed.

PTL 1 relates to a wiring board provided with differential signal wirings which are formed respectively as signal wirings for positive and negative signals and respectively in two different wiring layers. In the wiring board of PTL 1, differential signal wirings are formed in two different wiring layers, respectively. In the wiring board of PTL 1, two wirings together corresponding to one pair in terms of differential signal wirings are formed respectively in two different wiring layers, in a manner not to overlap with each other. In PTL 1, design values are set such that a predetermined parameter calculated on the basis of the amount of deviation between two signal wirings constituting one pair, widths of the signal wirings and the thickness of an insulating layer between the signal wirings be within a certain range. PTL 1 describes that the transmission loss of differential signals can be suppressed by designing in a manner to make the predetermined parameter satisfy a condition.

Patent Literature 2 (PTL 2) discloses a method of optimally arranging vias in a wiring board. In PTL 2, vias are arranged at respective lattice points, and whether the via arrangement is appropriate or not is determined on the basis of presence or absence of a via at each of the lattice points and wiring characteristics. PTL 2 describes that, by thus arranging vias at respective lattice points and performing evaluation, a state of excess or lack of vias can be prevented.

Further, Patent Literature 3 (PTL 3) discloses a technology which suppresses the difference in the amount of delay between differential signal wirings by appropriately setting line widths of the signal wirings. PTL 3 relates to a wiring board provided with differential signal wirings formed on an insulating layer including a glass cloth inside. In PTL 3, line widths of signal wirings are each set to be 75 to 95% of the weave interval of the glass cloth, that is, the interval of glass fibers. Thus, PTL3 describes that, by setting wiring widths to be within a certain range with reference to the weave interval of a glass cloth, change of a transmission time difference can be suppressed.

### CITATION LIST

### Patent Literature

[PTL 1] Japanese Laid-Open Patent Application No. 2008-109331
[PTL 2] Japanese Laid-Open Patent Application No. 2012-53726
[PTL 3] Japanese Laid-Open Patent Application No. 2014-130860

### SUMMARY OF INVENTION

### Technical Problem

However, the technology of PTL 1 is unsatisfactory in terms of the following point. While the technology of PTL 1 takes into account average characteristics of the insulating layer intervening between the two signal wirings formed in different layers, it does not take into account a difference in characteristics between the glass cloth and the resin at portions where the wirings actually pass. Accordingly, in PTL 1, when two signal wirings are formed on respective insulating layers having different electrical characteristics in a case the electrical characteristics of the insulating layers varies laterally with position, there occurs a difference in loss and the amount of delay between the signals. The technology of PTL 2 is the one for via arrangement in lateral direction. PTL 2 also does not take into account lateral variation, with portion where the wirings actually pass, of the electrical characteristics of the insulating layer. Accordingly, similarly to PTL 1, between two signal wirings used as differential signal wirings, there may occur a difference in loss and the amount of delay due to a difference in the electrical characteristics of the insulating layer. For these reasons, the technologies of PTL 1 and PTL 2 are unsatisfactory as those for suppressing a delay difference between two signal wirings constituting differential signal wirings.

The technology of PTL 3 sets wiring widths to be within a certain range with reference to the interval of the glass cloth in the insulating layer. Accordingly, in PTL 3, the wiring widths are largely limited by the interval of the glass cloth. In signal wirings to be used as a transmission line of high frequency signals, there is also large limitation on the electrical characteristics of the signal wirings in terms of transmitting the high frequency signals in a manner of suppressing their attenuation or the like. Therefore, when the wiring widths are limited to be within a certain range, the electrical characteristics need to be secured by adjusting parameters such as thicknesses of the wirings, which may cause large limitation on the design or make it impossible to design an operable wiring board. Further, in the technology of PTL 3, no rule is prescribed for positions where wirings are to be formed, and accordingly, in some cases of respective positions of two differential signal wirings, there may occur a difference in the amount of delay between the signals due to a difference in the electrical characteristics of the insulating layer. For this reason, the technology of PTL 3 is unsatisfactory as that for suppressing a difference in delay between two signal wirings constituting differential signal wirings while securing flexibility in design.

The present invention is aimed at achieving a wiring board which can suppress a difference in the amount of delay between two signal wirings constituting differential signal wirings while securing flexibility in design.

### Solution to Problem

To solve the above-described problem, a wiring board of the present invention includes a first insulation layer, a first signal wiring and a second signal wiring. The first insulating layer includes fibers having the long axis in a first direction and aligned approximately parallel to each other at a first interval, and an insulating material filling gaps between the fibers. The first signal wiring is formed approximately parallel to the first direction on the first insulating layer. The second signal wiring is formed parallel to the first signal wiring such that the interval between the first and second signal wirings be approximately an integral multiple of the first interval, and transmits a differential signal of a signal transmitted on the first signal wiring.

A wiring board fabrication method of the present invention includes forming a first signal wiring and a second signal wiring on a first insulating layer including fibers having the long axis in a first direction and aligned approximately parallel to each other at a first interval, and a first insulating material filling gaps between the fibers of the first direction. The first signal wiring is formed approximately parallel to the first direction. The second signal wiring is formed parallel to the first signal wiring such that the interval between the first and second signal wirings be approximately an integral multiple of the first interval.

A wiring board design method of the present invention includes selecting, as glass cloths to be used for a first insulating layer and a second insulating layer, a first glass cloth in which fibers having the long axis in a first direction are aligned approximately parallel to each other at a first fiber interval and a second glass cloth in which fibers having the long axis in a third direction are aligned approximately parallel to each other at a third fiber interval, in a manner to have the first and third fiber intervals coincide with each other. The wiring board design method of the present invention includes arranging, between the first and second insulating layers, a first signal wiring and a second signal wiring to transmit a differential signal of a signal transmitted on the first signal wiring. The wiring board design method of the present invention includes arranging the first and second signal wirings parallel to the first direction such that the interval between the first and second signal wirings be approximately an integral multiple of the first fiber interval.

### Advantageous Effects of Invention

According to the present invention, it becomes possible to suppress the difference in the amount of delay between two signal wirings constituting differential signal wirings while securing flexibility in design.

### BRIEF DESCRIPTION OF DRAWINGS

FIG. 1 is a diagram showing an outline of a configuration in a first example embodiment of the present invention.

FIG. 2 is a diagram showing an outline of a configuration in a second example embodiment of the present invention.

FIG. 3 is a diagram showing part of the configuration of the second example embodiment of the present invention.

FIG. 4 is a diagram showing an example of a configuration of a glass cloth used in the second example embodiment of the present invention.

FIG. 5 is a diagram showing part of a configuration of the second example embodiment of the present invention.

FIG. 6 is a diagram schematically showing a positional relationship between signal wirings and a glass cloth in the second example embodiment of the present invention.

FIG. 7 is a diagram showing an example of delay in differential signals.

FIG. 8 is a diagram showing an example of delay times for signals on differential signal wirings in a configuration to be compared with the present invention.

FIG. 9 is a diagram showing an example of insertion losses for signals on the differential signal wirings in the configuration to be compared with the present invention.

FIG. 10 is a diagram showing an example of delay times for signals on differential signal wirings in the second example embodiment of the present invention.

FIG. 11 is a diagram showing an example of insertion losses for signals on the differential signal wirings in the second example embodiment of the present invention.

FIG. 12 is a diagram showing an outline of a wiring board design flow in the second example embodiment of the present invention.

FIG. 13 is a diagram showing examples of characteristics of glass cloths in the second example embodiment of the present invention.

FIG. 14 is a diagram showing an example of another configuration according to the present invention.

### Example Embodiment

### First Example Embodiment

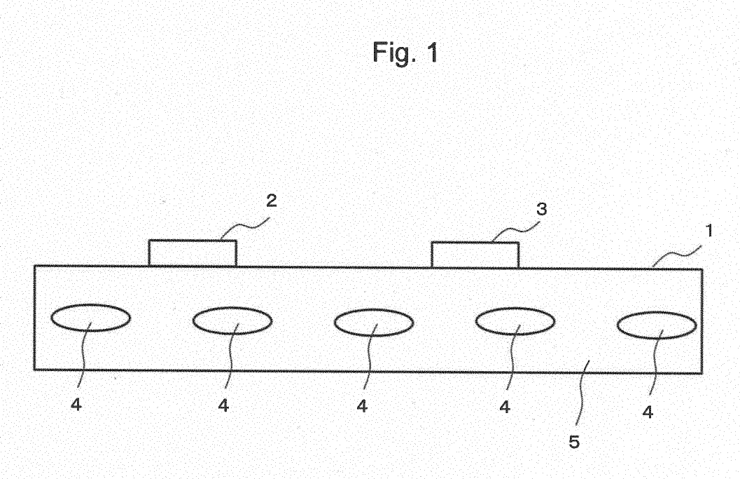

A first example embodiment of the present invention will be described in detail, with reference to drawings. FIG. 1 is a diagram showing an outline of a configuration of a wiring board of the present example embodiment. The wiring board of the present exemplary embodiment includes a first insulating layer 1, a first signal wiring 2 and a second signal wiring 3. The first insulating layer 1 includes fibers 4 having the long axis in a first direction and aligned approximately parallel to each other at a first interval, and an insulating material 5 filling gaps between the fibers 4 of the first direction. The first signal wiring 2 is formed approximately parallel to the first direction on the first insulating layer 1. The second signal wiring is formed parallel to the first signal wiring such that the interval between the first and second signal wirings be approximately an integral multiple of the first interval, and transmits a differential signal of a signal transmitted on the first signal wiring.

In the wiring board of the present example embodiment, the first signal wiring 2 is formed, on the first insulating layer 1, to be approximately parallel to the fibers 4 which have the long axis in the first direction and are aligned approximately parallel to each other at the first interval. Further, in parallel to the first signal wiring 2, the second signal wiring 3 for transmitting a differential signal of a signal transmitted on the first signal wiring 2 is formed such that the interval between the first signal wiring 2 and the second signal wiring 3 be approximately an integral multiple of the first interval.

By thus setting the interval between the first signal wiring 2 and the second signal wiring 3 to be an integral multiple of the first interval of the fibers 4 in the first insulating layer 1, the area ratio between the fibers 4 and the insulating material 5 becomes almost the same for portions where the first signal wiring 2 passes and portions where the second signal wiring 3 passes. Accordingly, the influences which a signal transmitted on the first signal wiring 2 and that transmitted on the second signal wiring 3 respectively receive from the electrical characteristics of the first insulating layer 1 become almost the same. As a result, it becomes possible to suppress the difference in the amount of delay between the differential signals transmitted on the first signal wiring 2 and the second signal wiring 3. Further, as the interval between the first signal wiring 2 and the second signal wiring 3 can be selected to be an integral multiple of the first interval of the fibers 4 of the first insulating layer 1, it becomes possible to suppress decrease of flexibility in the wiring design. Thus, in the wiring board of the present example embodiment, it becomes possible to suppress the difference in the amount of delay between two signal wirings constituting differential signal wirings while securing flexibility in design.

### Second Example Embodiment

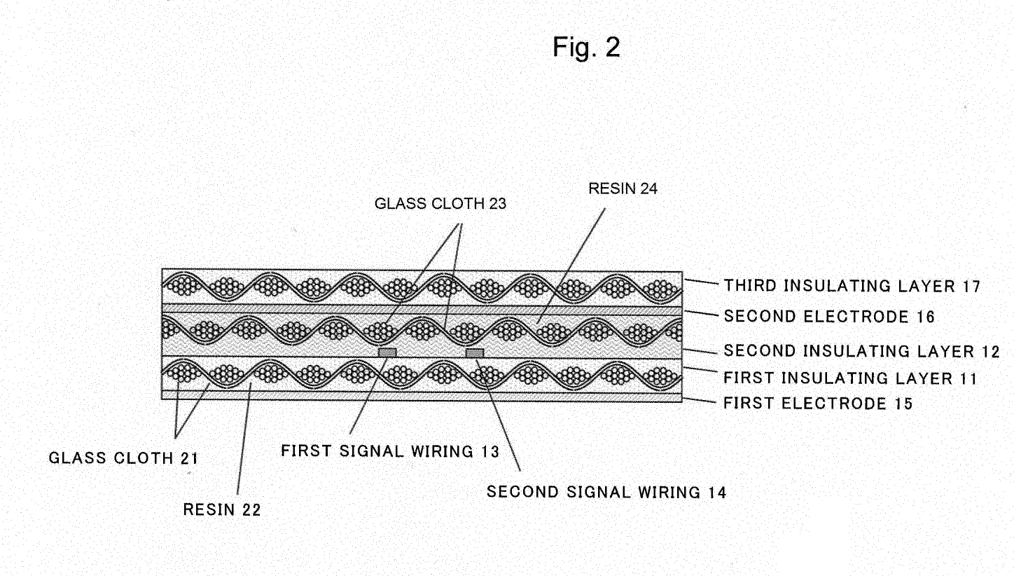

A second example embodiments of the present invention will be described in detail, with reference to drawings. FIG. 2 is a diagram showing an outline of a configuration of a wiring board of the present example embodiment.

The wiring board of the present example embodiment includes a first insulating layer 11, a second insulating layer 12, a first signal wiring 13, a second signal wiring 14, a first electrode 15 and a second electrode 16. Further, above the second insulating layer 12, a third insulating layer 17 is laminated across the second electrode 16 intervening in-between.

The wiring board of the present example embodiment is a printed circuit board having a multilayer wiring structure. In the wiring board of the present example embodiment, the first insulating layer 11 and the third insulating layer 17 each function as a core material. Further, the second insulating layer 12 is a prepreg material used when forming a laminated multilayer wiring board by pressure bonding. The first signal wiring 13 and the second signal wiring 14 are signal wirings for transmitting differential signals in a high frequency range. In the present example embodiment, positive and negative signals are transmitted, respectively, on the first signal wiring 13 and the second signal wiring 14.

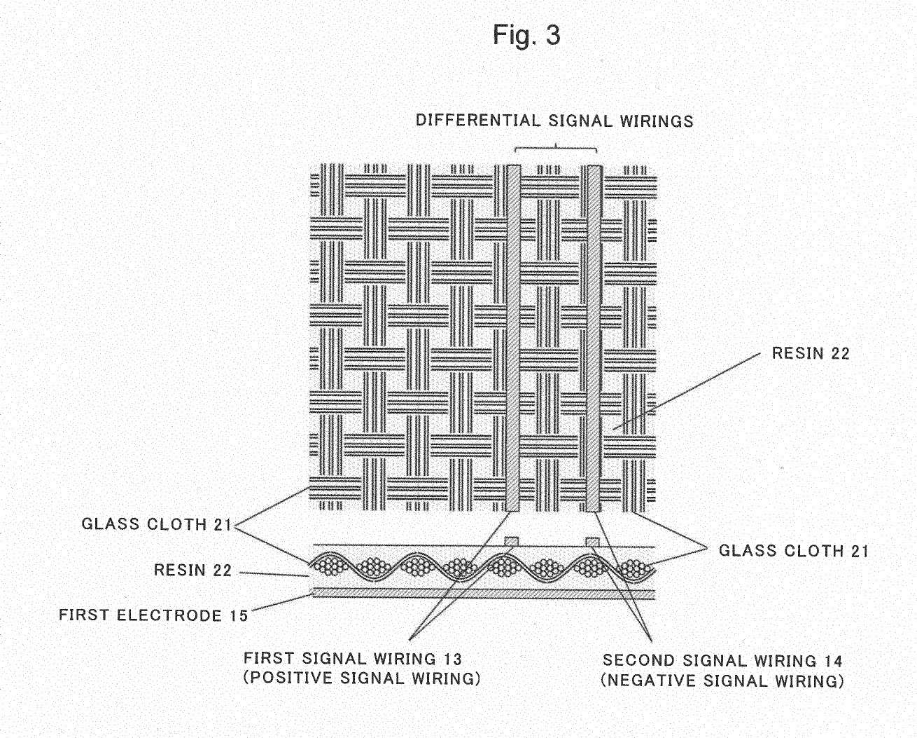

FIG. 3 is a diagram showing part of the wiring board shown in FIG. 2, where the first insulating layer 11, the first signal wiring 13 and the second signal wiring 14 are included. The upper section of FIG. 3 shows a plan view of the wiring board. The lower section of FIG. 3 shows a cross-sectional view of the wiring board illustrated in the same way as FIG. 2, where a cross-sectional view of a part including the first insulating layer 11, the first signal wiring 13 and the second signal wiring 14 is shown.

The first insulating layer 11 includes a glass cloth 21 and a resin 22. The first insulating layer 11 serves a function to maintain the structure and mechanical strength of the wiring board, as a core material of the wiring board.

The glass cloth 21 functions as a structural material of the first insulating layer 11. In the glass cloth 21, as shown in the upper section of FIG. 3, glass fibers of two different directions are woven together by plain weaving, in a manner to make the two directions perpendicular to each other. The direction of glass fibers is referred to as a direction parallel to the long axis of the glass fibers. In the present example embodiment, the two directions described above are called a first direction and a second direction, respectively.

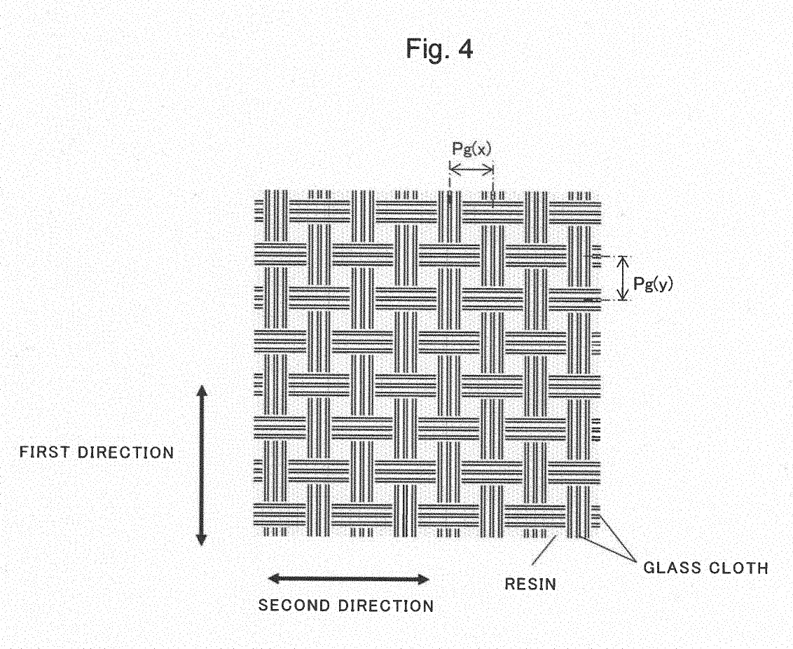

FIG. 4 is a diagram showing only the glass cloth 21. In the glass cloth 21 of the present example embodiment, bundles of fiber glasses having the long axis in the first direction are aligned parallel to each other at an approximately constant interval. In the present example embodiment, the interval of the glass fibers having the long axis in the first direction is denoted by Pg(x). Further, bundles of glass fibers having the long axis in the second direction perpendicular to the first direction are aligned parallel to each other, similarly. In the present example embodiment, when it is described that bundles of glass fibers are parallel to each other, it means that bundles of fibers of the same direction are arranged in a manner to have no intersection between them and align their long axes with each other, and accordingly can be regarded as almost parallel. In the present example embodiment, the interval of the glass fibers having the long axis in the second direction is denoted by Pg(y). The glass fiber intervals Pg(x) and Pg(y) are each a distance between the centers of glass fiber bundles each formed with some number of glass fibers. In the glass cloth 21 of the present example embodiment, bundles of fibers of the first direction and those of the second direction are woven by plain weaving, in a manner to make the two directions perpendicular to each other. When perpendicularly intersecting with the fiber bundles of the second direction, each of the fiber bundles of the first direction crosses alternately over and under the fiber bundles of the second direction, bundle by bundle.

The resin 22 has an insulating property. Gaps between the glass fibers in the glass cloth 21 are filled with the resin 22. For example, epoxy resin may be used for the resin 22. The first insulating layer 11 of the present example embodiment corresponds to the first insulating layer 1 of the first example embodiment. The resin 22 of the present example embodiment corresponds to the insulating material 5. The glass fibers in the glass cloth 21 of the present example embodiment correspond to fibers 4 of the first example embodiment.

The second insulating layer 12 includes a glass cloth 23 and a resin 24. Materials of the glass cloth 23 and of the resin 24 are the same as, respectively, those of the glass cloth 21 and of the resin 22 of the first insulating layer 11. The intervals of glass fibers in the glass cloth 23 used for the second insulating layer 12 of the present example embodiment are the same as those in the glass cloth 21 of the insulating layer 11.

The first signal wiring 13 and the second signal wiring 14 are provided as wirings for transmitting high frequency differential signals. On the first signal wiring 13 and the second signal wiring 14, signals having phases opposite to each other are transmitted. The first signal wiring 13 and the second signal wiring 14 are formed to be parallel to each other. Further, the first signal wiring 13 and the second signal wiring 14 are formed with their straight portions aligned parallel to the first or second direction. The “being parallel to the first direction” means that straight portions of the signal wirings can be regarded as almost parallel to the first direction. Similarly, the “being parallel to the second direction” means that straight portions of the signal wirings can be regarded as almost parallel to the second direction. For example, when the first signal wiring 13 (parallel to the first direction) is in a state of not intersecting with any of a plurality of glass fiber bundles having the long axis in the first direction, the first signal wiring 13 can be regarded as parallel to the first direction. The interval between the first signal wiring 13 and the second signal wiring 14 is set to be a positive integral multiple of the interval of the glass fibers having the long axis in a direction parallel to the signal wirings.

The first signal wiring 13 of the present example embodiment corresponds to the first signal wiring 2 of the first example embodiment. Similarly, the second signal wiring 14 of the present example embodiment corresponds to the second signal wiring 3 of the first example embodiment.

When Pdx denotes the interval between the first signal wiring 13 and the second signal wiring 14 which are parallel to the first direction, the wiring interval Pdx is set to satisfy Pdx=NxXPg(x). Nx is a natural number. It is desirable that a value of the wiring interval Pdx calculated from the interval of the glass cloth Pg(x) has accuracy to the second or lower decimal place in millimeter, in consideration of fabrication error. Accordingly, a value of Nx denoting the rate of integral multiplication also is not required to be exactly an integer, and an Nx value whose deviation from a certain integer is at the second or lower decimal place, that is, less than 0.10 may be regarded as the integer. Therefore, hereafter, what to be called an integer multiple includes also a value in a state of being approximately an integer multiple where the value deviates from an integer by less than 0.10.

When Pdy denotes the interval between the first signal wiring 13 and the second signal wiring 14 which are parallel to the second direction, the wiring interval Pdy is set to satisfy Pdy=NxXPg(y). Ny is a natural number. Similarly to the case of the first direction, it is desirable that a value of the wiring interval Pdy calculated from the interval of the glass cloth Pg(y) has accuracy to the second or lower decimal place in millimeter. Accordingly, also a value of Ny denoting the rate of integral multiplication is not required to be exactly an integer, and an Ny value whose deviation from a certain integer is at the second or lower decimal place, that is, less than 0.10 may be regarded as the integer.

Nx and Ny may be values different from each other. When signal wirings of the first direction and those of the second direction are connected to form electrically continuous signal wirings, it is desirable to set Pdx and Pdy to be the same. By thus making the interval of wirings constant even at a bending section, it becomes possible to increase the possibility of making constant the ratio between the glass cloth and resin in every portion where the wirings pass, and thereby to decrease the difference in the amount of delay between the signals even at the bending section.

It is not necessarily required to employ entirely over the wiring board the configuration of arranging signal wirings parallel to the direction of glass fibers and at an interval equivalent to a positive integral multiple of the interval of the glass fibers. For example, the configuration is not necessarily required to be applied to global wirings such as common power supply and ground wirings and to wirings for transmitting low speed signals. Applying the structure of the present example embodiment to differential signal wirings for transmitting giga range high speed signals between semiconductor devices and electronic components mounted on a wiring board, it becomes possible to achieve an effect of suppressing the amount delay. Further, a particularly large effect can be achieved when employed in an area of a narrow wiring pitch within a wiring board. It is because the influence of electrical characteristics of the insulating layers on signal delay is larger for finer wirings.

Line widths and thicknesses of the first signal wiring 13 and of the second signal wiring 14 are set to make characteristic impedances be in accordance with a design of the wiring board. The first signal wiring 13 and the second signal wiring 14 of the present example embodiment are formed using copper. The first signal wiring 13 and the second signal wiring 14 may also be formed using another metal or formed as an alloy of a plurality of metals.

The first electrode 15 is arranged on the opposite side to the first signal wiring 13 and the second signal wiring 14, across the first insulating layer 11. The first electrode 15 is formed using copper. The first electrode 15 may also be formed using another metal or as an alloy of a plurality of metals. The first electrode 15 of the present example embodiment constitutes strip lines, together with the first signal wiring 13 and the second signal wiring 14. A GND voltage is applied to the first electrode 15. While the signal wirings are configured in the form of strip lines in the present example embodiment, they may also be configured in the form of microstrip lines.

The second electrode 16 is arranged on the opposite side to the first signal wiring 13 and the second signal wiring 14, across the second insulating layer 12. The material of the second electrode 16 is the same as that of the first electrode 15. The GND voltage is applied to the second electrode 16 of the present example embodiment. To the first electrode 15 and the second electrode 16, a power supply voltage may also be applied.

The third insulating layer 17 has the same configuration as that of the first insulating layer 11.

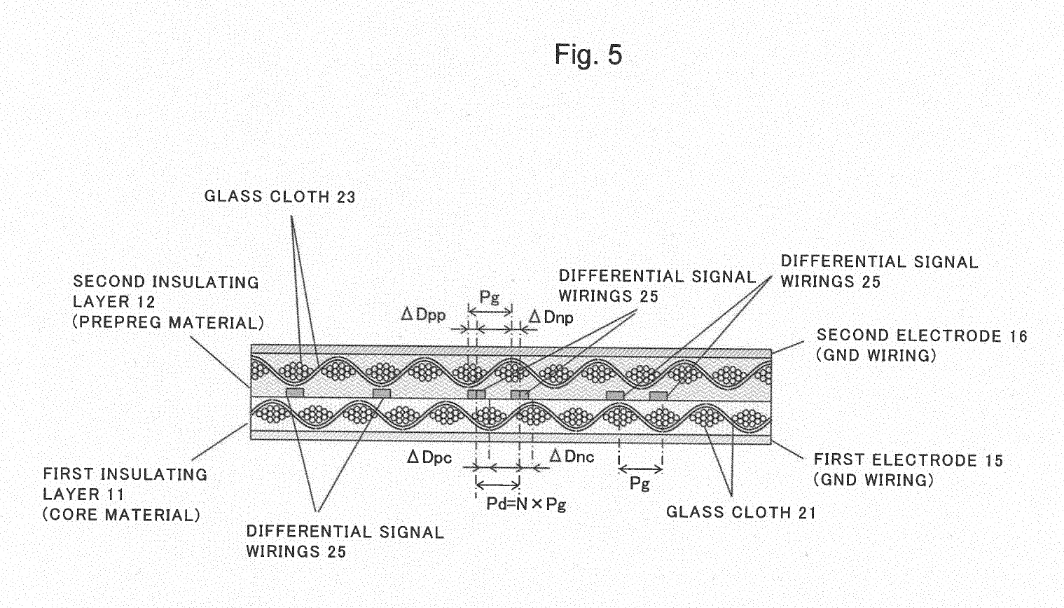

With reference to FIG. 5, the wiring board of the present example embodiment will be described in more detail. FIG. 5 shows a structure of a part of the wiring board shown in FIG. 2 corresponding to that including the first insulating layer 11 and the second insulating layer 12. In FIG. 5, three pairs of differential signal wirings 25 are formed between the first insulating layer 11 and the second insulating layer 12. Each pair of differential signal wirings 25 is formed of a combination of the first signal wiring 13 and the second signal wiring 14.

The differential signal wirings 25 formed of two signal wirings at the center of FIG. 5 are formed in a manner to equalize the wiring interval Pg with the interval Pd of both of the glass cloths in the first insulating layer 11 and in the second insulating layer 12. Between the central two signal wirings, the left one is assumed to be a signal wiring for positive signals, and the right one to be that for negative signals. Further, deviation between the signal wiring for positive signals and glass fibers of the glass cloth 21 in the first insulating layer 11 is denoted by ΔDpc, and deviation between the signal wiring for negative signals and glass fibers in the first insulating layer 11 is denoted by ΔDnc. Then, it turns out that ΔDpc=ΔDnc, and accordingly, the overlap width between the signal wiring for positive signals and glass fibers in the first insulating layer 11 becomes the same as that between the signal wiring for negative signals and glass fibers in the first insulating layer 11. Therefore, the influence in electrical characteristics received from the first insulating layer 11 is almost the same for the positive and negative signals.

Similarly, deviation between the signal wiring for positive signals and glass fibers of the glass cloth 23 in the second insulating layer 12 is denoted by ΔDpp, and deviation between the signal wiring for negative signals and glass fibers in the second insulating layer 12 is denoted by ΔDnp. Then, it turns out that ΔDpp=ΔDnp, and accordingly, the overlap width between the signal wiring for positive signals and glass fibers in the second insulating layer 12 becomes the same as that between the signal wiring for negative signals and glass fibers in the second insulating layer 12. Therefore, the influence in electrical characteristics received from the second insulating layer 12 is almost the same for the positive and negative signals. As a result, the influence in electrical characteristics received from both the first insulating layer 11 and the second insulating layer 12 becomes the same for the positive and negative signals, and accordingly, the amount of delay becomes the same for the positive and negative signals.

Further, in the wiring board of the present example embodiment, (the difference in) the amount of delay becomes the same for the positive and negative signals when the glass cloth 21 in the first insulating layer 11 and the glass cloth 23 in the second insulating layer 12 have the same interval and their long axis directions are parallel to each other. That is, the positive and negative signals receive the same influence even when positions of glass fibers of the glass cloth 21 in the first insulating layer 11 viewed from a direction perpendicular to the wiring board are not in coincidence with those of glass fibers of the glass cloth 23 in the second insulating layer 12. In the wiring board of the present example embodiment, it is only necessary, in laminating together the first insulating layer 11 and the second insulating layer 12, to adjust directions of glass fibers in the glass cloths, and the fabrication accordingly becomes easy.

The differential signal wirings 25 formed of two signal wirings at the left side of the wiring board in FIG. 5 have an interval of signal wirings equivalent to twice the interval of glass fibers. Even in that case, the amount of deviation from glass fibers in the first insulating layer 11 is the same for the two signal wirings, and also the overlap width with glass fibers is the same for the two signal wirings. Similarly, the two signal wirings have the same overlap width with glass fibers in the second insulating layer 12. Accordingly, the influence in electrical characteristics received from both the first insulating layer 11 and the second insulating layer 12 is almost the same for the positive and negative signals. As a result, the influence in electrical characteristics received from both the first insulating layer 11 and the second insulating layer 12 becomes almost the same for the positive and negative signals, and accordingly, (the difference in) the amount of delay becomes the same for the positive and negative signals. The above description applies also to a case where the interval of differential signal wirings is three times or a larger positive integral multiple of the interval of glass fibers.

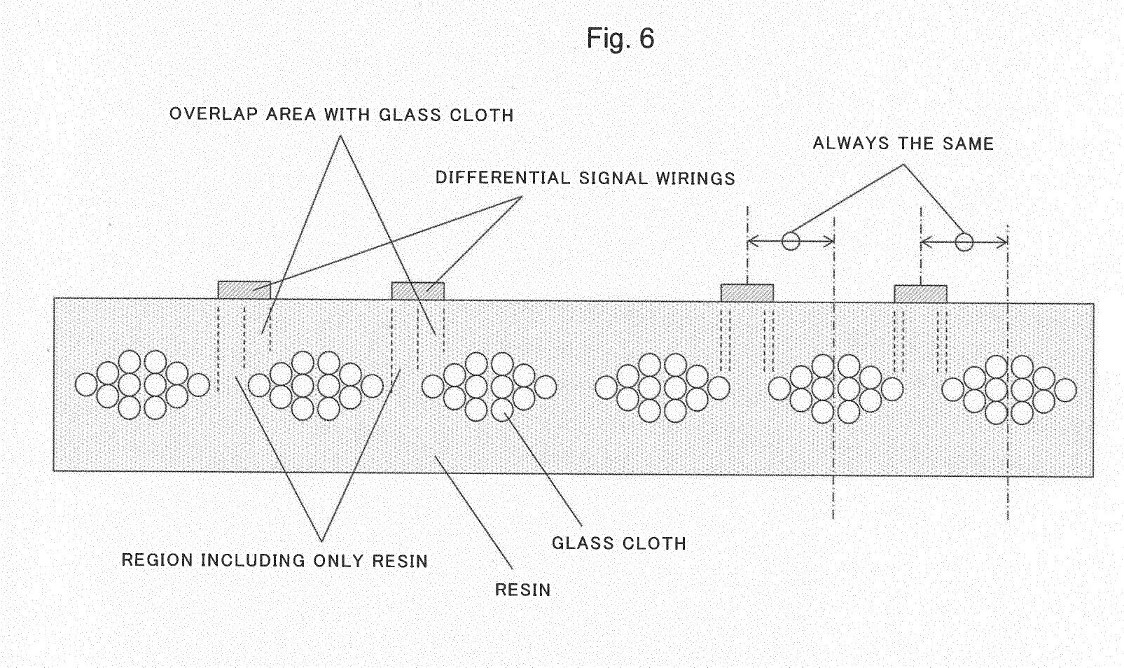

FIG. 6 is a diagram showing more schematically a part including the first insulating layer 11 and the differential signal wirings 25, of the wiring board shown in FIGS. 2 and 5. The overlap width with glass fibers of the glass cloth in the first insulating layer 11 is the same for the two signal wirings. Similarly, the overlap width with an area of the first insulating layer 11 including only resin is the same for the two signal wirings. As long as the interval of the signal wirings is a positive integral multiple of the interval of glass fibers in the glass cloth, the condition that the two signal wirings have the same overlap width with glass fibers and the same overlap width with the resin is realized. Further, also when the second insulating layer 12 is formed, in relation to the glass fibers and resin in the second insulating layer 12, the condition that the two signal wirings have the same overlap width with glass fibers and the same overlap width with the resin is realized, similarly. As a result, the influence in electrical characteristics received from both the first insulating layer 11 and the second insulating layer 12 becomes the same for positive and negative signals, and accordingly, it becomes possible to suppress the difference in the amount of delay between the positive and negative signals.

The effect of suppressing the difference in the amount of delay between positive and negative signals can be achieved even when horizontal positions of glass fibers of the first insulating layer 11 are not in coincidence with those of glass fibers of the second insulating layer 12. That is, by setting the wiring interval to be a positive integral multiple of the interval of glass fibers, the influence of deviation in a direction perpendicular to the long axis on the difference in the amount of delay between positive and negative signals becomes small. In the wiring board of the present example embodiment, when laminating together the core material and the glass fibers in fabrication of the wiring board, it is not required to exactly manage the amount of deviation of the glass fibers in a direction perpendicular to the long axis of both the glass fibers and signal wirings, and accordingly, complication of the fabrication process can be prevented.

Operation of the wiring board of the present example embodiment will be described below. In the wiring board of the present example embodiment, a high frequency positive signal is input to the first signal wiring 13 from one end of the signal wiring, transmitted to the output side and is output there. Further, a negative signal having the same frequency as and the opposite phase to the positive signal is input to the second signal wiring 14 from one end of the signal wiring, transmitted to the output side and is output there. The positive and negative signals are transmitted on strip lines configured with the first signal wiring 13, the second signal wiring 14 and the first electrode 15. The positive signal to be transmitted on the first signal wiring 13 and the negative signal to be transmitted on the second signal wiring 14 are input as differential signals, and the differential signals are processed by a semiconductor device or an electronic device connected to the output side.

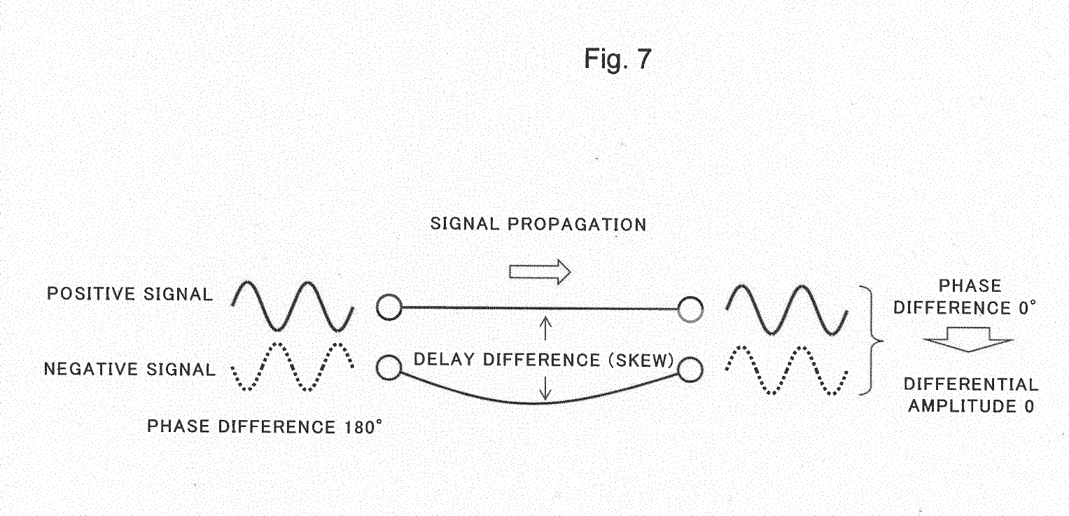

A description will be given of the effect of suppressing the difference in the amount of delay between positive and negative signals when using the wiring board of the present example embodiment. FIG. 7 is a diagram showing an example of signal delay generated by differential signal wirings, using a phase difference. In the left section of FIG. 7, signals at a time of inputting differential signals to the wiring board are illustrated. In the right section of FIG. 7, an example of output signals are illustrated. At a time of their input, the differential signals are input such that positive and negative signals have opposite phases. That is, at the time of their input to the wiring board, the phase difference between the positive and negative signals is 180 degrees. In the positive and negative signals' propagating on the signal wirings on the wiring board, they receive the influence of electrical characteristics of the wiring board, and there accordingly is generated a delay difference (skew) between them.

In the example of FIG. 7, illustrated is a case where a delay difference, that is, a difference in the amount of phase delay of 180 degrees is generated, and as a result, the phase difference between the positive and negative signals becomes zero degree at the time of their output. In the differential signal scheme, the amplitude difference between the signals is increased by setting them to have opposite phases, which makes signal detection at the output side easy. Therefore, when the phases are shifted to be, for example, the same phase at the output side, the amplitude difference becomes small, and accordingly, there may occur abnormality that signal detection cannot be correctly performed at the output side. For this reason, when using differential signals, it is required to suppress the delay difference between the signals to be as small as possible.

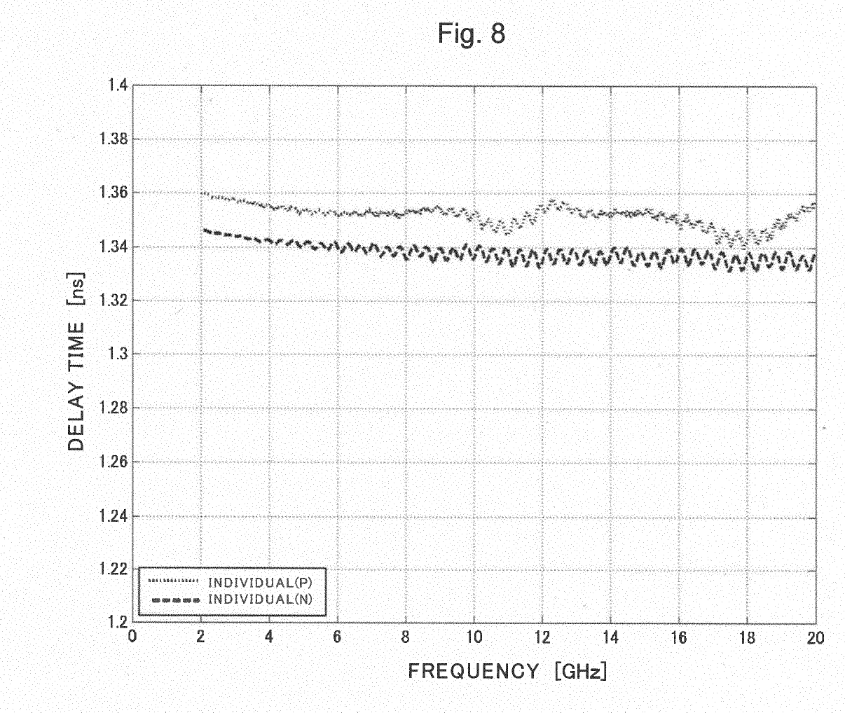

FIG. 8 is a diagram showing the amount of signal delay in a structure in which a positive signal wiring is arranged in an area where the proportion of glass fibers in the glass cloth is highest and a negative signal wiring is arranged in an area where the proportion of a resin is highest, for comparison with the wiring board of the present example embodiment. In FIG. 8, setting the horizontal axis to represent frequency and the vertical axis to represent delay time (Group Delay), delay times of the positive signal (individual (P)) and of the negative signal (individual (N)) are shown.

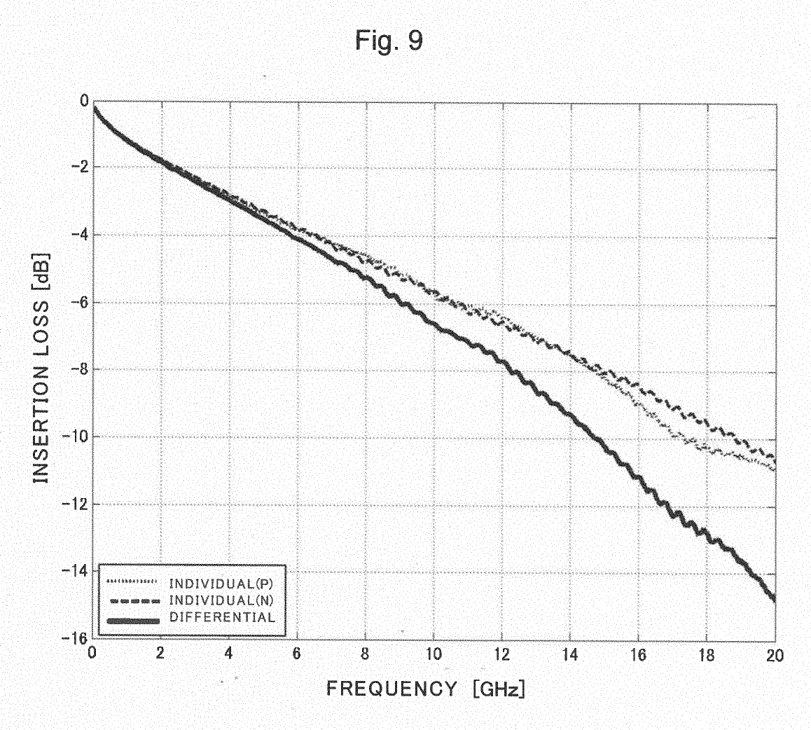

FIG. 9 is a diagram showing insertion losses of the signals in the same structure as that of FIG. 8 as a function of frequency, setting the vertical axis to represent insertion loss. Decrease of amplitude difference as a result of deviation of the phase relation between the positive and negative signals from the opposite phase state is one of causes of insertion loss generation. As shown in FIG. 9, the positive and negative signals are in an unbalanced state at a frequency of 20 GHz. That is, while the insertion losses of the individual signals are each about −10 dB, the insertion loss of the differential signal (differential) becomes about −15 dB.

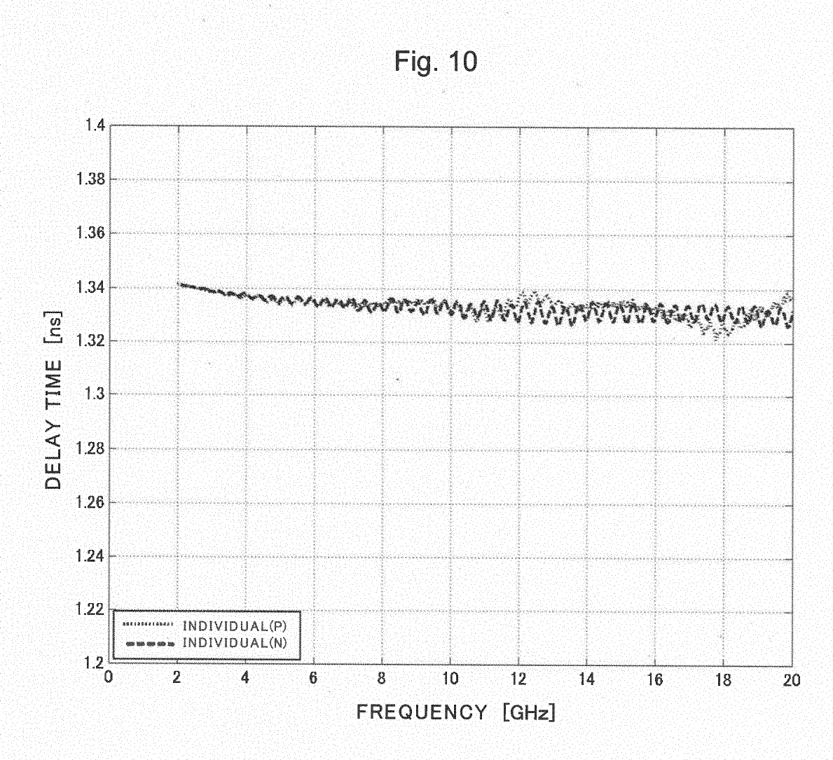

FIG. 10 is a graph showing frequency dependence of delay times in the wiring board of the present example embodiment. Similarly to FIG. 8, setting the horizontal axis to represent signal frequency and the vertical axis to represent signal delay time, the graph of FIG. 10 shows delay times of positive and negative signals. Comparing FIGS. 8 and 10, it is noticed that the delay difference between the positive and negative signals is smaller in FIG. 10 showing delay times in the wiring board of the present example embodiment.

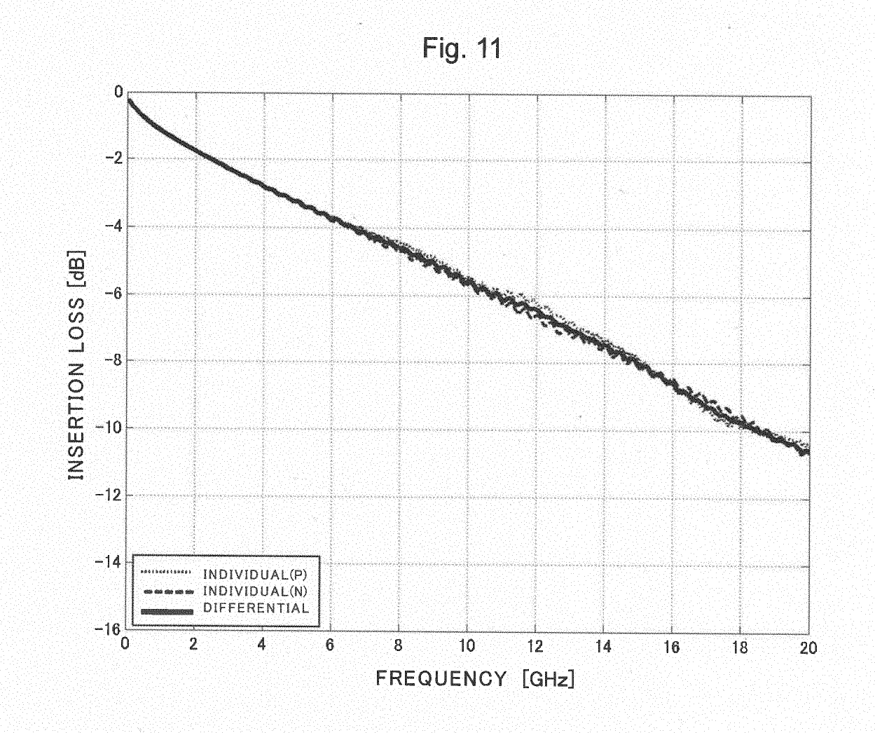

FIG. 11 is a diagram showing insertion losses of the differential signals transmitted on the wiring board of the present example embodiment as a function of frequency, setting the vertical axis to represent insertion loss. As shown in FIG. 11, in the case of using the wiring board of the present example embodiment, the insertion loss is almost the same for the positive and negative signals and also for the differential signal, being about −10 dB at 20 GHz. As the insertion loss of the differential signal is about −15 dB at 20 GHz in the example of FIG. 9, the insertion loss is reduced by using the wiring board having the configuration of the present example embodiment. Thus, in the wiring board of the present example embodiment, by setting the ratio between passing over glass cloth areas and passing over resin areas to be the same for the signal wirings for positive and negative signals, the difference in the amount of delay is suppressed and the insertion loss of the differential signal is reduced.

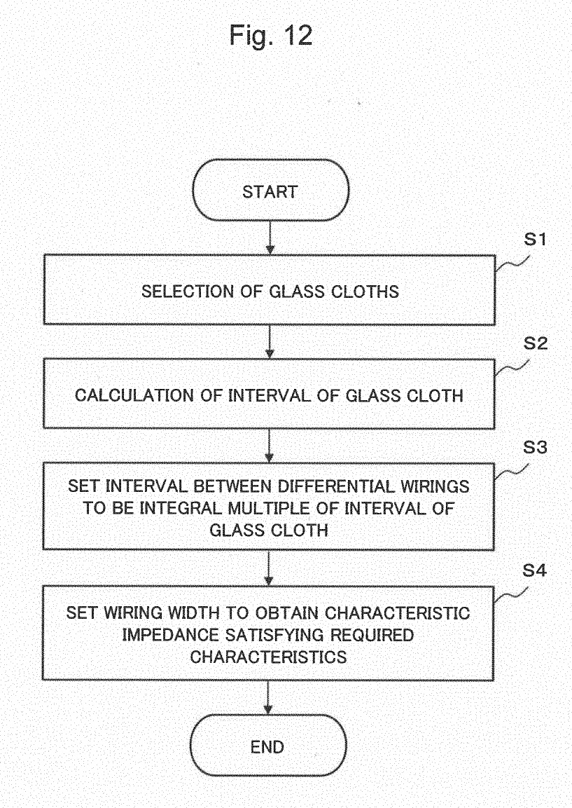

Next, a design method of the wiring board of the present example embodiment will be described. FIG. 12 is a diagram showing an outline of a flow of setting glass cloths and a wiring interval, in a design stage of the wiring board of the present example embodiment. The design method of the wiring board of the present example embodiment mainly consists of four steps described below.

(Step 1) In selecting a core material and a prepreg material, that is, structural materials for the first insulating layer 11 and for the second insulating layer 12, glass cloths having the same glass cloth number are selected as glass cloths having the same characteristics.

By using glass cloths having the same glass cloth number, the interval of glass fibers becomes the same for the glass cloth 21 in the first insulating layer 11 and for the glass cloth 23 in the second insulating layer 12. That is, in the step 1, selection of glass cloths having the same glass fiber interval is performed, as glass cloths to be used for the first insulating layer 11 and for the second insulating layer 12.

(Step 2) The interval of glass cloth Pg is calculated from the glass cloth density of the selected glass cloths.

(Step 3) Based on the interval of glass cloth Pg, the wiring interval of differential signal wirings Pd is set. That is, the wiring interval Pd between the first signal wiring 13 and the second signal wiring 14 is set to be a positive integral multiple of Pg. When the glass cloths have an interval Pg(x) in one direction and a different interval Pg(y) in a direction perpendicular to the one direction, wiring intervals are set for the respective directions separately. It is desirable that a value of the wiring interval Pd calculated from the interval of glass cloth Pg is set to the second or lower decimal place in millimeter, in consideration of fabrication error.

(Step 4) A width of the wirings is determined to obtain a predetermined impedance. The predetermined impedance is determined, in accordance with required characteristics of the wiring board, on the basis of characteristics affecting the electrical characteristics of the wirings, such as the relative dielectric constant, a width of the wirings, a wiring interval and insulating layer thicknesses.

Based on a wiring interval design rule thus obtained, design of a wiring pattern to be formed on the wiring board of the present example embodiment is performed.

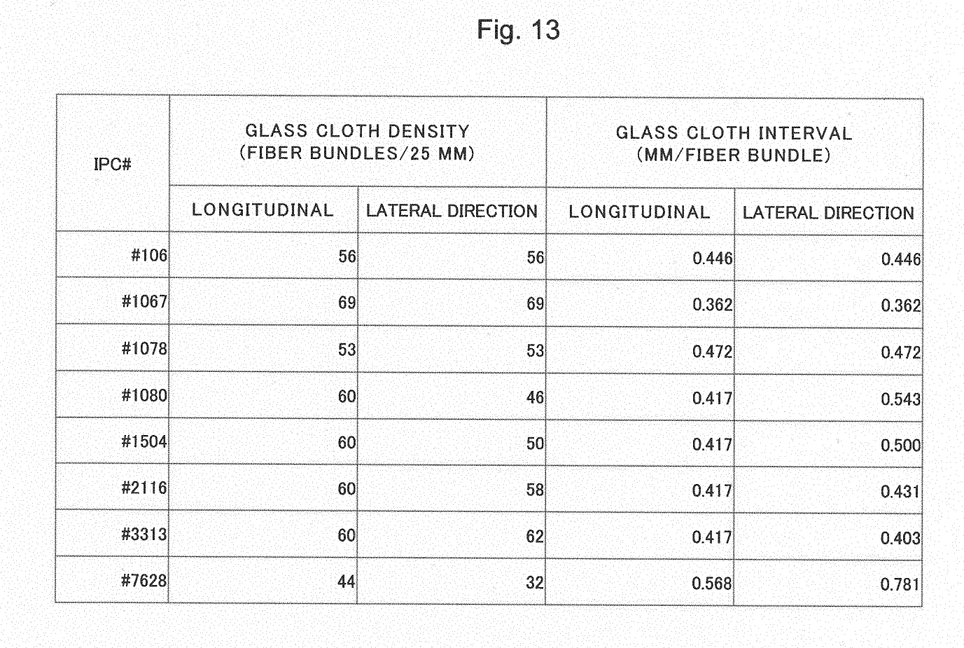

FIG. 13 is a table showing examples of the interval of glass cloth calculated from the density of glass cloth. IPC# in the table of FIG. 13 indicates glass cloth numbers prescribed by IPC (Association Connecting Electronics Industries, former name: Institute for Interconnecting and Packaging Electronics Circuits). By selecting glass cloths having the same glass cloth number for the first insulating layer 11 and for the second insulating layer 12, glass cloths having the same glass fiber interval in glass cloth can be selected for the insulating layers.

Glass cloth densities of FIG. 13 each indicate the number of glass fibers included in 25 mm. There, a glass cloth density is shown for each of longitudinal and lateral directions of each of the glass cloths formed by plain weaving. For example, the longitudinal direction corresponds to the first direction in the present example embodiment, and the lateral direction to the second direction. As each of the glass cloth intervals, a value obtained by the calculation of an interval of the glass cloth from the glass cloth density is shown for each of the longitudinal and lateral directions.

Next, a fabrication method of the wiring board of the present example embodiment will be described. First, on the first insulating layer 11, a wiring pattern for the first signal wiring 13 and the second signal wiring 14 and the first electrode 15 are formed. Straight portions of the wiring pattern for the first signal wiring 13 and the second signal wiring 14 are formed along the long axis direction of glass fibers in the glass cloth. The long axis direction of glass fibers in the glass cloth was arranged to be directed in a predetermined direction when forming the first insulating layer 11. When it is assumed to be rectangular or square, the wiring board of the present example embodiment is formed such that each of the first and second directions of the glass cloth be a direction parallel to an end surface of the wiring board. The case of assuming a rectangular or square wiring board is referred to as a case where, when a notch or the like is present on an end surface of the board, a contour of the board is estimated assuming that the notch portion is absent.

Diagonally bending portions of the signal wirings are formed such that the parallel state between the first signal wiring 13 and the second signal wiring 14 is maintained and the interval between them is kept the same as that in straight portions. Metal layers used for the first signal wiring 13, the second signal wiring 14 and the first electrode 15 are each formed by sticking a copper foil sheet on a surface of the first insulating layer 11. Alternatively, the metal layers may be deposited by sputtering. In the present example embodiment, copper is used for the metal layers. Further, the wiring pattern for the first signal wiring 13 and the second signal wiring 14 is formed by photolithography after the metal layer formation.

When forming the wiring pattern by photolithography, signal wirings parallel to a long axis of glass fibers can be formed by aligning the direction of the signal wiring with the long axis direction of the glass fibers using an alignment marker formed on the wiring board in advance. The direction alignment in the formation of signal wirings may also be performed using the contour of the wiring board.

After the formation of the wiring pattern or the like on it, the first insulating layer 11 is laminated with a prepreg material used as the second insulating layer 12 and the third insulating layer 17 connected across the prepreg material. On the third insulating layer 17, a wiring pattern and an electrode are formed similarly to on the first insulating layer 11. The number of insulating layers made of core materials to be laminated as above may be three or larger. Further, the wiring board may be that including only the first insulating layer 11.

When laminating the first insulating layer 11 with the prepreg material for the second insulating layer 12, the lamination is performed such that the axis directions of glass cloth be in coincidence between the two layers. The axis directions of glass cloth is referred to as the long axis directions of glass fibers constituting the glass cloth. Further, along each axis, the interval is the same for glass fibers in the glass cloth constituting the first insulating layer 11 and for those in the glass cloth constituting the prepreg material for the second insulating layer 12. In the present example embodiment, the design is made such that the axis directions of glass cloth can be adjusted by making adjustment using the contour.

After laminating together the first insulating layer 11, the second insulating layer 12 being a prepreg material and other insulating layers, the layers are formed into a single wiring board by pressure bonding. After the formation of a single wiring board, the wiring board is completed by forming through holes and a wiring pattern on the most external layer, as necessary, cutting the board and the like. On the completed wiring board, semiconductor devices and electronic components are mounted, which are then used as an electronic circuit for transmitting high frequency signals.

In the wiring board of the present example embodiment, the first signal wiring 13 and the second signal wiring 14 are formed, as differential signal wirings, on the first insulating layer 11 corresponding to a core material of the wiring board. The wiring interval between the first signal wiring 13 and the second signal wiring 14 is set to be a positive integral multiple of the interval of glass fibers in the first insulating layer 11 which have the long axis in the same direction as the longitudinal direction of both the first signal wiring 13 and the second signal wiring 14. By setting the wiring interval between the differential signal wirings to be an integral multiple of the interval of glass fibers in the insulating layer, the volume ratio between glass fibers and a resin becomes the same for a portion where the positive signal passes and for a portion where the negative signal passes. As a result, the influence from electrical characteristics of the insulating layer becomes almost the same for positive and negative signals transmitted on the differential signal wirings.

The same effect can be achieved in relation to also the interval of glass fibers in the prepreg material used for the second insulating layer 12, by setting the wiring interval between the first signal wiring 13 and the second signal wiring 14 to be a positive integral multiple of the interval of glass fibers in the second insulating layer 12. As a result, the influence received from electrical characteristics of both the above and underlying insulating layers becomes almost the same for the two signal wirings constituting the differential signal wirings. By thus making the influence from the insulating layers almost the same, it becomes possible to suppress the difference in the amount of delay between positive and negative signals transmitted on the differential signal wirings. As a result of thus suppressing the difference in the amount of delay between positive and negative signals transmitted on the differential signal wirings, it becomes possible to reduce the insertion loss of differential signals transmitted on the wiring board of the present example embodiment.

In the wiring board of the present example embodiment, it is only required that the wiring interval between the first signal wiring 13 and the second signal wiring 14 is a positive integral multiple of the interval of glass fibers constituting the first insulating layer 11 and of those constituting the second insulating layer 12, and it accordingly becomes possible to prevent decrease of flexibility in arrangement of the signal wirings. Therefore, in the wiring board of the present example embodiment, flexibility in wiring design can be secured. Thus, in the wiring board of the present example embodiment, it is possible to suppress the difference in the amount of delay between two signal wirings constituting differential signal wirings while securing flexibility in design.

Further, in the wiring board of the present example embodiment, as long as the long axis direction of glass fibers constituting the first insulating layer 11 and that of glass fibers constituting the second insulating layer 12 are almost parallel to each other, the suppression of the difference in the amount of delay can be achieved even when glass fibers' positions in a direction perpendicular to the long axis direction are not in coincidence between the two insulating layers. Accordingly, lamination of the first insulating layer 11 and the second insulating layer 12 becomes easy. As a result, the wiring board of the present example embodiment becomes easy to fabricate.

In the second example embodiment, the description has been given of an example of application to a wiring board including strip lines composed of differential signal wirings and a GND electrode formed on a side of an insulating layer opposite to the differential signal wirings. The configuration with the wiring interval between differential signal wirings being set to be a positive integral multiple of the fiber interval of a glass cloth may be applied also to planar lines. That is, the configuration with the wiring interval between differential signal wirings being set to be a positive integral multiple of the fiber interval of a glass cloth may be applied to a wiring structure in which differential wirings are formed parallel to a GND wiring which is formed in the same layer as or a different layer from that of the differential wirings.

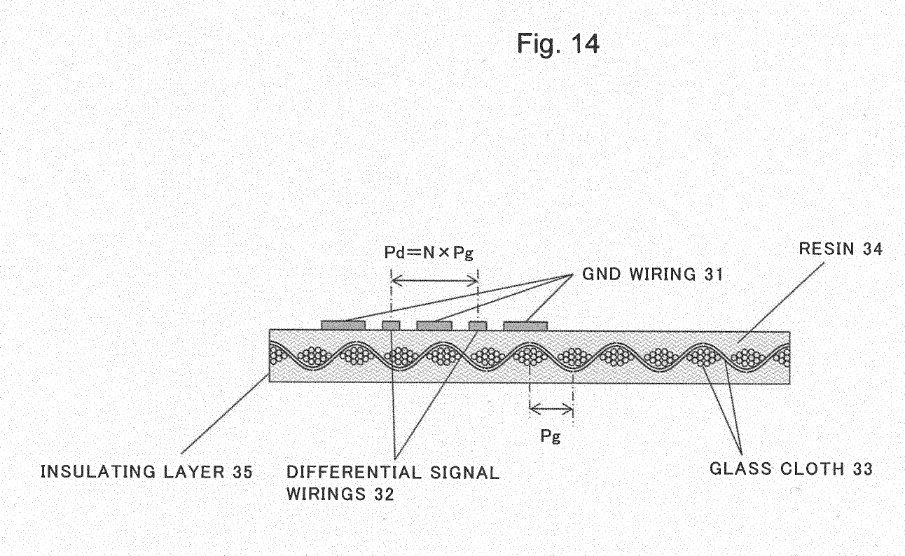

FIG. 14 is a diagram schematically showing a structure of planar lines with the wiring interval between differential signal wirings being set to be an integral multiple of the fiber interval of a glass cloth. A wiring board having the planar line wiring structure shown in FIG. 14 includes GND wirings 31, differential signal wirings 32, a glass cloth 33, a resin 34 and an insulating layer 35. The GND wirings 31 correspond to the first electrode 15 of the wiring board in FIG. 2 The differential signal wirings 32 correspond to the first signal wiring 13 and the second signal wiring 14 of the wiring board in FIG. 2. The glass cloth 33 and the resin 34 are the same as the components denoted by the same names in the wiring board of FIG. 2. The insulating layer 35 corresponds to the first insulating layer 11 of the wiring board in FIG. 2

In the example of FIG. 14, the two differential signal wirings 32 are each formed between the GND wirings 31. Further, the wiring interval Pd between the differential signal wirings 32 is set to be N times the interval Pg of glass fibers in the glass cloth. N is a natural number. Setting the configuration as described above, the same effect as that in the second example embodiment can be achieved. Further, in such a planar wiring structure, it is difficult to set the wiring interval Pd between the two differential signal wirings to be the same as the interval Pg of glass fibers in the glass cloth, because one of the GND wiring 31 is present between the differential signal wirings. Therefore, the effect of integral multiplication by an integer N equal to or larger than 2 becomes larger than that in the case of microstrip lines.

While the example of FIG. 14 has been described as an example in terms of one direction, the configuration of FIG. 14 may be further applied to also a direction perpendicular to the glass cloth 33, the differential signal wirings 32 and the like, similarly to in the second example embodiment. Further, similarly applying the configuration of FIG. 14 relating to a glass cloth and a wiring interval to another insulating layer, an effect of suppressing the difference in the amount of delay can be achieved.

The present invention has been described above taking the example embodiments as exemplary ones. However, the present invention is not limited to the example embodiments described above. That is, to the present invention, various aspects which can be understood by those skilled in the art may be applied within the scope of the present invention.

This application is based upon and claims the benefit of priority from Japanese Patent Application No. 2015-9817 filed on Jan. 21, 2015, the disclosure which is incorporated herein in its entirety by reference.

### REFERENCE SIGNS LIST

1 first insulating layer
2 first signal wiring
3 second signal wiring
4 fiber
5 insulating material
11 first insulating layer
12 second insulating layer
13 first signal wiring
14 second signal wiring
15 first electrode
16 second electrode
17 third insulating layer
21 glass cloth
22 resin
23 glass cloth
24 resin
25 differential signal wirings
31 GND wiring
32 differential signal wirings
33 glass cloth
34 resin
35 insulating layer

What is claimed is:

1. A wiring board comprising:
a first insulating layer comprising fibers having a long axis in a first direction and aligned approximately parallel to each other at a first interval and an insulating material filling gaps between the fibers of the first direction;
a first signal wiring formed approximately parallel to the first direction on the first insulating layer; and
a second signal wiring formed parallel to the first signal wiring such that an interval between the first and second wirings be approximately an integral multiple of the first interval, the second wiring transmitting a differential signal of a signal transmitted on the first signal wiring.

2. The wiring board according to claim 1 further comprising
a second insulating layer comprising fibers having a long axis in a third direction approximately parallel to the first direction and aligned approximately parallel to each other at the first interval and a second insulating material filling gaps between the fibers of the third direction, wherein
the first insulating layer and the second insulating layer together form a laminated structure.

3. The wiring board according to claim 2, wherein:
the first insulating layer further comprises fibers having a long axis in a second direction different from the first direction and aligned approximately parallel to each other at a second interval, and the first insulating material further fills gaps between the fibers of the second direction; and
the second insulating layer further comprises fibers having a long axis in a fourth direction approximately parallel to the second direction and aligned approximately parallel to each other at the second interval, and the second insulating material further fills gaps between the fibers of the second direction.

4. The wiring board according to claim 3 further comprising:
a third signal wiring formed approximately parallel to the second direction; and
a fourth signal wiring formed parallel to the third signal wiring such that an interval between the third and fourth wirings be approximately an integral multiple of the second interval, the fourth wiring transmitting a differential signal of a signal transmitted on the third signal wiring.

5. The wiring board according to claim 2, wherein:
the first signal wiring and the second signal wiring are formed on a surface of the first insulating layer; and
a gap between the first signal wiring and the second signal wiring is filled with the second insulating layer.

6. A wiring board fabrication method comprising
forming, on a first insulating layer comprising fibers having a long axis in a first direction and aligned approximately parallel to each other at a first interval and an insulating material filling gaps between the fibers of the first direction:
a first signal wiring to be formed approximately parallel to the first direction; and
a second signal wiring parallel to the first signal wiring such that an interval between the first and second wirings be approximately an integral multiple of the first interval.

7. The wiring board fabrication method according to claim 6 comprising
forming a second insulating layer comprising fibers having a long axis in a third direction approximately parallel to the first direction and aligned approximately parallel to each other at the first interval and a second insulating material with gaps between the fibers of the third direction are filled, such that the first insulating layer and the second insulating layer together form a laminated structure.

8. The wiring board fabrication method according to claim 7 comprising:
forming the first signal wiring and the second signal wiring on a surface of the first insulating layer; and
forming the second insulating layer such that a gap between the first signal wiring and the second signal wiring be filled with the second insulating layer.

9. A wiring board design method comprising:
selecting a first glass cloth including fibers having a long axis in a first direction and aligned approximately parallel to each other at a first fiber interval and selecting a second glass cloth including fibers having a long axis in a third direction and aligned approximately parallel to each other at a third fiber interval, as glass cloths to be used for a first insulating layer and a second insulating layer, respectively, such that the first fiber interval and the third fiber interval be the same; and
arranging, between the first insulating layer and the second insulating layer, a first signal wiring and a second signal wiring for transmitting a differential signal of a signal transmitted on the first signal wiring, such that the first signal wiring and the second signal wiring be approximately parallel to the first direction and an interval between them be approximately an integral multiple of the first fiber interval.

10. The wiring board design method according to claim 9, wherein
in the selection of glass cloths to be used for the first insulating layer and the second insulating layer, respectively,
the glass cloths are selected such that a second fiber interval of fibers perpendicular to the first direction included in the first glass cloth and a fourth fiber interval of fibers perpendicular to the third direction included in the second glass cloth be the same further.
